(19) United States
(12) Patent Application Publication
(10) Pub. No.: US 2002/0044071 A1
(43) Pub. Date: Apr. 18, 2002

(54) Keyboard structure with a reeling device

(75) Inventor: Chen Ding-Yuu, Taoyuan (TW)

Correspondence Address: DOUGHERTY & TROXELL, 5205 LEESBURG PIKE, SUITE 1404, FALLS CHURCH, VA, 22041, US

(73) Assignee: Darfon Electronics Corp.

(21) Appl. No.: 09/964,327

(22) Filed: Sep. 28, 2001

(30) Foreign Application Priority Data
Oct. 5, 2000 (TW) 89217317

(51) Int. Cl. H03M 11/00; H03K 17/94

(52) U.S. Cl. 341/22; 361/680

(57) ABSTRACT

A keyboard structure with a reeling device includes a reeling cartridge and an accommodation slot constructed at a lateral side of the keyboard for receiving the separable reeling cartridge. The reeling cartridge further includes a casing, a reeling mechanism and a signal transmission wire. The signal transmission wire fed by the reeling mechanism is capable of connecting electrically a built-in driver circuitry of the keyboard with a computer mainframe for forwarding key-in commands from the keyboard to the computer mainframe. By providing the accommodation slot and the reeling cartridge, the signal transmission wire can be stored inside with the keyboard.

### BACKGROUND OF THE INVENTION

(1) Field of the Invention

The invention relates to a keyboard structure with a reeling device, and more particularly to a keyboard which can accept a reeling cartridge for collecting a transmission cable that communicates between the keyboard and a computer.

(2) Description of the Prior Art

It is well known in the art that a keyboard in the computer industry is applied to direct a user's command to an input device of a computer. The keyboard, in general, includes at least a plurality of buttons representing individual symbols. By providing the keyboard, user's commands can be realized, through organized button knocking, and then can be forwarded to the computer for further processing.

Generally, the keyboard as a basic accessory to a computer system can communicate with the computer through an appropriate transmission system. The transmission system can be a wire type that communicates with the computer through a transmission cable, or can be a wireless type that communicates with the computer through an ultra-red device as an example. By providing a wireless ultra-red transmission system, the keyboard can communicate signals theoretically with the computer without any solid cable connection in between. Terminologically, such kind of keyboards is said to be a wireless keyboard. For mobility and convenience provided by the wireless keyboard, it is the trend now that the wireless keyboards become popular more and more.

Referring now to FIG. 1, a conventional computer system with a wireless keyboard is shown. The computer system 10 includes a computer mainframe 11, a monitor 12 and the wireless keyboard 13. As shown, the monitor 12 is integrated as a unique piece to the computer mainframe 11 which includes thereinside a CPU as well as other electronic and electric components (not shown in the figure). The computer mainframe 11 further includes an ultra-red receiver 14 located at a proper position thereof. The wireless keyboard 13 as shown includes a plurality of buttons 15 with distinct individual symbols and an ultra-red sender 16 for matching in communication with the ultra-red receiver 14 on the computer mainframe 11. While a user pushes the buttons 15 of the wireless keyboard 13, the ultra-red sender 16 will forward the command from the user to the computer mainframe 11 through the ultra-red receiver 14 for further processing in the CPU.

To prevent the ultra-red transmission between the sender 16 and the receiver 14 from any electronic interference or from any ill realizability caused by a possible power shortage, an optional signal transmission wire 17 can be utilized to establish a solid connection between the wireless keyboard 13 and the computer mainframe 11 for assuring accurate signal transmission in between. As shown, the signal transmission wire 17 has two terminals for connecting with the wireless keyboard 13 and the computer mainframe 11, respectively. Yet, it is noted that the signal transmission wire 17 is an optional accessory and is too tiny to be noticeable in general. So, it is quite possible that the user will happen to loose it somehow, and it is always the case that the user can't locate the signal transmission wire 17 upon a moment in urgent need of it. Under such a circumstance, the transmission quality of the computer system 10 is inevitably degraded or evenly interrupted.

It is the fact that the signal transmission wire 17 in the art is an exceptional part for the computer system 10 and is seldom used in a normal operation environment. However, upon a particular moment that needs the signal transmission wire 17 but just unable to locate it, the prevailing frustration and hopelessness are inevitable.

It can be foreseen that a reeling apparatus integrated with the wireless keyboard for collecting the signal transmission wire can resolve the aforesaid problem. By providing the reeling apparatus, the signal transmission wire can be stored in the wireless keyboard while not in use, and can be extended to reach the computer mainframe while in use. Upon such an arrangement, the problem of missing the signal transmission wire can be definitely settled.

### SUMMARY OF THE INVENTION

Accordingly, it is a primary object of the present invention to provide a keyboard structure with a reeling device that can provide a built-in signal transmission wire for forwarding the key-in command to the computer mainframe while the signal transmission wire being in an extended state.

The keyboard structure with a reeling device in accordance with the present invention is applied to a wireless keyboard which communicates generally with the computer mainframe through ultra-red. The computer mainframe includes an ultra-red receiver and a cable socket. The wireless keyboard includes a plurality of buttons and an ultra-red sender. In a normal operation, a user can work on the keyboard to have plenty of commands forward to the computer mainframe through the ultra-red transmission for further processing in the central processing unit in the computer mainframe.

One of the many characteristics of the present invention is that the keyboard includes a signal transmission wire and a reeling cartridge. A first terminal of the signal transmission wire is fixed at the keyboard, and a second terminal thereof is to be plugged into a respective cable socket of the computer mainframe. The commands from the keyboard can be transmitted to the computer mainframe by the signal transmission wire. The reeling cartridge located inside an accommodation slot of the keyboard includes an interior reeling mechanism for collecting the signal transmission wire to prevent from possible missing of the tiny signal transmission wire. While the signal transmission wire is required, it can be quickly and conveniently fed from the reeling cartridge to establish wire transmission between the keyboard and the computer mainframe.

All these objects are achieved by the keyboard structure with a reeling device described below.

### BRIEF DESCRIPTION OF THE DRAWINGS

The present invention will now be specified with reference to its preferred embodiment illustrated in the drawings, in which

FIG. 1 is a schematic view of a conventional computer system with a wireless keyboard;

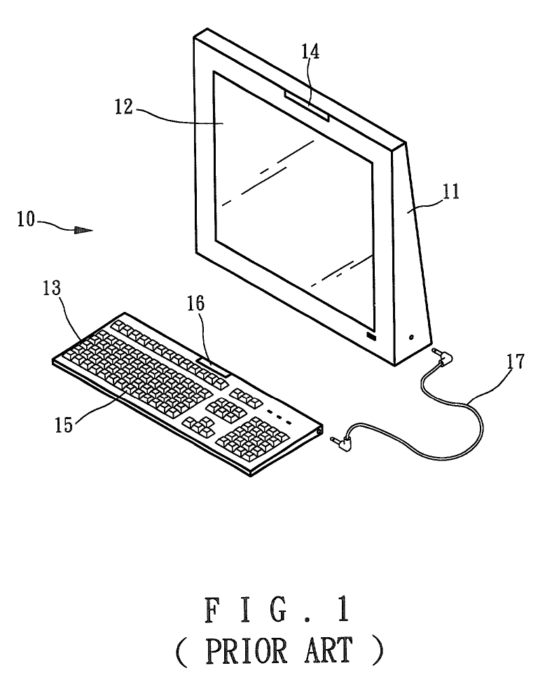

FIG. 2 is a schematic view of a computer system having a preferred wireless keyboard with a reeling device in accordance with the present invention;

FIG. 3 is an exploded view of a preferred reeling cartridge in accordance with the present invention;

FIG. 4A is a schematic view showing the preferred actuator in a stop state; and

FIG. 4B is a schematic view showing the preferred actuator in a let-go state.

### DESCRIPTION OF THE PREFERRED EMBODIMENT

The invention disclosed herein is directed to a keyboard structure with a reeling device. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

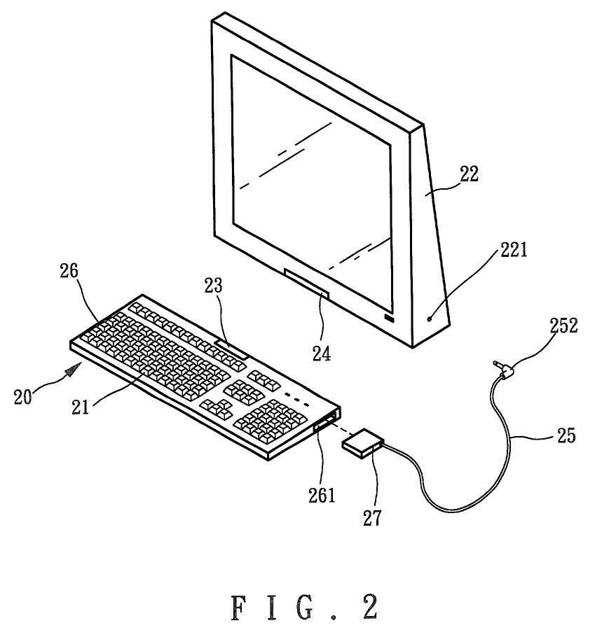

Referring now to FIG.2, a schematic view showing the wireless keyboard with a reeling device is present. The wireless keyboard 20 includes a plurality of buttons 21 and is capable of wireless communicating with the computer mainframe 22. As shown, the wireless keyboard 20 further includes an ultra-red sender 23, and respectively the computer mainframe 22 includes an ultra-red receiver 24.

As described in previous background section, though the wireless keyboard 20 can communicate wireless with the computer mainframe 22 without many limitations on mobility, yet signal interference and power shortage are still possible to interrupt the wireless communication in between. To overcome such disadvantages upon the wireless transmission, the present invention introduces an additional signal transmission wire 25 for providing one terminal thereof to connect electrically with a driver circuitry of the wireless keyboard 20 and another terminal to connect with the computer mainframe 22. By providing the signal transmission wire 25, the wireless keyboard 20 can establish a countable wire communication with the computer mainframe 22.

Though the present invention provides a signal transmission wire 25 similar to that in the art for ensuring correct signal transmission anyhow, yet the major difference between the present invention and the art is that the wireless keyboard 20 of the present invention includes a signal transmission wire 25, a keyboard body 26 and a reeling cartridge 27. The signal transmission wire 25 has a first terminal (not shown in the figure) located inside the reeling cartridge 27 for connecting electrically with the keyboard body 26 and a second terminal 252 to be plugged into a respective cable socket 221 of the computer mainframe 22. According to the present invention, as long as the second end 252 of the signal transmission wire 25 connects with the cable socket 221 of the computer mainframe 22, the ultra-red sender 23 of the wireless keyboard 20 can be nullified. That is all the transmission then between the wireless keyboard 10 and the computer mainframe 22 is through the signal transmission wire 25.

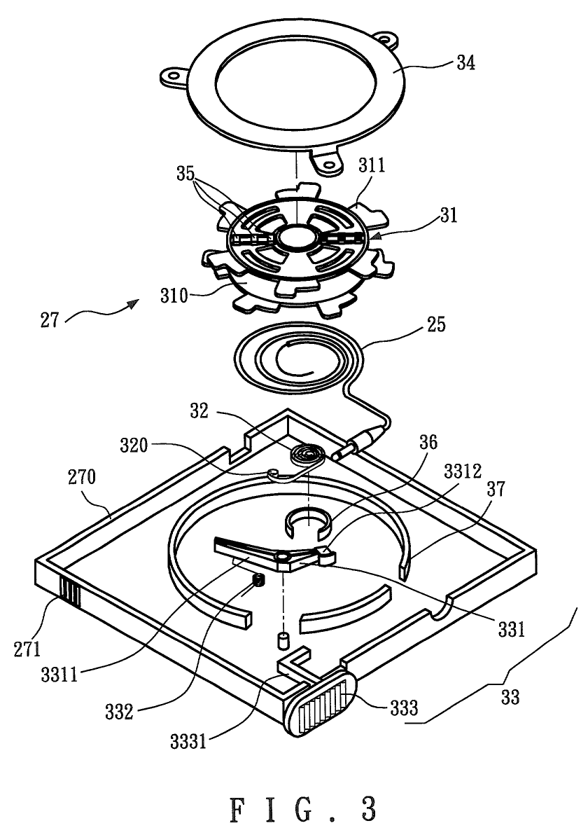

Referring now to FIG. 2 and FIG. 3, the reeling cartridge 27 is formed to be separable from the accommodation slot 261 of the keyboard body 26. The casing 270 of the reeling cartridge 27 includes a first contact port 271 connecting with the first terminal of the transmission wire 25, and on the other hand the accommodation slot 261 includes a respective second contact port (not shown in the figures) connecting with the built-in driver circuitry of the wireless keyboard 20. While the reeling cartridge 27 is anchored inside the accommodation slot 261 to have the first contact port 271 engaged with the second contact port, electric connection as well as the signal transmission between the wireless keyboard 20 and the computer mainframe 22 can be established. The reeling cartridge 27 includes an internal reeling mechanism for collecting the signal transmission wire 25 while not in usage and for feeding the signal transmission wire 25 to the computer mainframe 22 while in usage. In addition, the signal transmission wire 25 can also play as a power cable that connects with a rechargeable battery (not shown in the figure) inside the wireless keyboard 20. The battery is used to provide electricity to the ultra-red sender 23. By providing such a connection, power of the computer mainframe 22 can be used to recharge the battery inside the wireless keyboard 20. Thus, the power shortage problem that hinders the ultra-red sender 23 from a normal operation can be resolved.

Referring now to FIG.3, the reeling mechanism can include a reel 31, a torsion spring 32, an actuator 33, a cover 34 and a plurality of dividers 35.

Preferably, a hoop-like wire housing 37 can be provided to out-shield the reel 31 and to provide a disc space for allowing the reel 31 to rotate thereinside. As shown, while the reel 31 rotates counterclockwise, the signal transmission wire 25 can be rewound into a receiving groove 310 of the reel 31. While the reel 31 rotates clockwise, the signal transmission wire 25 can then be fed or extended from the receiving groove 310 of the reel 31.

The torsion spring 32 is accommodated by a spring housing 36 in the casing 270 and has a protrusive end 320 to outreach and engage with the reel 31. According to the present invention, the torsion spring 32 is used to provide elasticity for rotating the reel counterclockwise so as to rewind the signal transmission wire 25 into the receiving groove 310. By providing the torsion spring 32, potential spring energy can be stored into the torsion spring for later rewinding usage while the signal transmission wire 25 is pulled to extend through rotating the reel 31 clockwise. The torsion spring can be a worm spring, a constant-forcing spring, or any the like. Preferably, the torsion spring 32 is a constant-forcing spring having a fixed spring constant for obtaining a constant rotation speed of the reel 31 while rewinding the signal transmission wire 25.

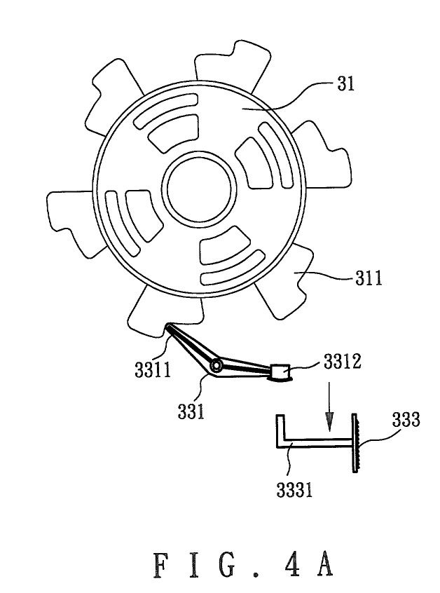

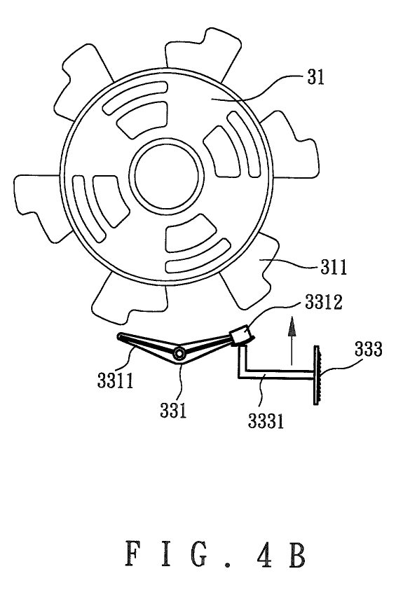

The actuator 33 of the present invention can generate a reaction force to act against the torsion of the torsion spring 32 while the signal transmission wire 25 is pulling outward. The reaction is applied so as to prevent the reel 31 from rewinding the signal transmission wire 25 automatically by the torsion of the torsion spring 32 while the pulling of the signal transmission wire 25 is interrupted. To achieve the aforesaid goal, the actuator 33 include an actuating arm 331, an elastic element 332 and a control button 333. The actuator 33 utilizes elasticity of the elastic element 332 to drive a first end 3311 of the actuating arm 331 to contact against one of peripheral stoppers 311 of the reel 31. As shown, the control button 333 of the actuator 33 can have a control arm 3331 protruding toward a second end 3312 of the actuating arm 331. While the control button 333 is pushed to have the control arm 3331 push the second end 3312 of the actuating arm 331, the first end 3311 of the actuating arm 331 can be separated pivotally from the stopper 311 for relieving the reel 31 from the actuating arm 331 so as to allow the torsion spring 32 into action to rewind the signal transmission wire 25 into the receiving groove 310; as shown in FIG. 4A and FIG. 4B consequently.

Referring to FIG. 3, the cover 34 shaped corresponding to the reel 31 is used to shield the reel 31 for ensuring the torsion spring 32 to be safely located under the reel 31. The dividers 35, preferably to be three, is used to fix one end of the signal transmission wire 25 to the reel 31, and to help the reel 31 smoothly wind the signal transmission wire 25 so as to have the reel 31 smoothly feed or collect the signal transmission wire 25.

As described above, a preferred embodiment for the keyboard structure with a reeling device has been disclosed. Regarding the reeling cartridge 27 of the embodiment, any rotating mechanism that can wind the signal transmission wire 25 can be a replacement. Yet, no more detail will be given in this description. In addition, the modularization provided by the reeling cartridge 27 introduces the advantage that the reeling cartridge 27 as well as the signal transmission wire 25 can be easily separable from the accommodation slot 261 of the keyboard body 26. Definitely, according to the present invention, the detachability of the reeling cartridge 27 can be removed by simply constructing the reeling mechanism into the keyboard body. Contrary, the reeling cartridge of present invention could be installed inside of the computer mainframe. The reeling cartridge can be received in and pulled out of the computer mainframe as same as while installed in the keyboard.

In accordance with the present invention, the keyboard structure with a reeling device has the following advantages over the prior art.

a. By providing the reeling device to the wireless keyboard, the signal transmission wire can be always stored with the keyboard while not in usage and can be easily utilized to establish a wire connection with the computer while in usage. No more loss problem of the signal transmission wire can be met.

b. By providing the power-cable capability to the signal transmission wire, the wireless keyboard can then be recharged by the computer through the signal transmission wire. Thus, seldom power shortage problem can be happened to the wireless keyboard.

c. By providing the reeling cartridge and the accommodation slot, the manufacturing upon the reeling device of the present invention can be easier.

While the present invention has been particularly shown and described with reference to a preferred embodiment, it will be understood by those skilled in the art that various changes in form and detail may be without departing from the spirit and scope of the present invention.

I claim:

1. A keyboard structure with a reeling device, comprising:
an accommodation slot, constructed at a lateral side of the keyboard;
a reeling cartridge to be plugged into the accommodation slot, the reeling cartridge having:
a casing;
a reeling mechanism, constructed inside the casing; and
a signal transmission wire, fed by the reeling mechanism, further having thereof a first terminal and a second terminal, the first terminal capable of connecting electrically with a built-in driver circuitry of the keyboard, and the second terminal used for connecting to a electrical device for forwarding key-in commands therethrough from the keyboard to the electrical device.

2. The keyboard structure with a reeling device according to claim 1, wherein said keyboard is a wireless keyboard having thereof an ultra-red sender for communicating with a respective ultra-red receiver constructed at said electrical device.

3. The keyboard structure with a reeling device according to claim 2, wherein said ultra-red sender is powered by said electrical device through said signal transmission wire.

4. The keyboard structure with a reeling device according to claim 2, wherein said ultra-red sender is powered by a rechargeable battery in said keyboard and the re-chargeable battery is recharged by said electrical device through said signal transmission wire.

5. The keyboard structure with a reeling device according to claim 1, wherein said electrical device includes a cable socket for receiving said second terminal of said signal transmission wire.

6. The keyboard structure with a reeling device according to claim 1, wherein when said keyboard is connected with said electrical device by said signal transmission wire, the communication between said electrical device and said keyboard takes place only through said signal transmission wire.

7. The keyboard structure with a reeling device according to claim 1, wherein said reeling mechanism of said reeling cartridge further includes:
a reel, further having thereof a receiving groove for winding said signal transmission wire; and
a torsion spring, engaged with the reel, for storing torsion energy while the reel is rotated to unwind said signal transmission wire out of the reel, and for relieving the torsion energy so as to wind automatically said signal transmission wire into the reel.

8. The keyboard structure with a reeling device according to claim 7, wherein said torsion spring is a constant-forcing spring that has a fixed spring constant.

9. The keyboard structure with a reeling device according to claim 7, wherein said reeling mechanism further has an actuator and said reel has thereof a perimeter with a plurality of extrusive stoppers, the actuator confronting with the stoppers to prevent said reel from automatically rewinding said signal transmission wire while said signal transmission wire is unwound.

10. The keyboard structure with a reeling device according to claim 9, wherein said actuator further has:
an elastic element;
a actuating arm, having thereof a first end and a second end, the first end being pushed against one of said stopper by the elastic element to prevent said extended signal transmission wire from being rewinding into said reel by said torsion spring; and
a control button, having thereof a control arm protruding toward the second end of the actuating arm, the control arm being pushed against the second end to separate the first end from said stopper for relieving said reel from the actuating arm so as to rewind said signal transmission wire into said reel while the control button is pushed.

11. The keyboard structure with a reeling device according to claim 10, wherein said elastic element is a spring.

12. The keyboard structure with a reeling device according to claim 7, wherein said reeling mechanism further has a cover to shielding said reel and to ensure said torsion spring safely located under said reel.

13. The keyboard structure with a reeling device according to claim 7, wherein said reeling mechanism further has a plurality of dividers located at said reel to help said reel smoothly wind said signal transmission wire and so as to have said reel smoothly feed or collect said signal transmission wire.

14. The keyboard structure with a reeling device according to claim 1, wherein said casing of said reeling cartridge includes thereof a first contact port connecting with said first terminal of said transmission wire and said accommodation slot includes thereof a respective second contact port connecting with said built-in driver circuitry of said keyboard, the first contact port engaging with the second contact port to establish electrically connection between said keyboard and said electrical device while said reeling cartridge is anchored inside said accommodation slot.

15. The keyboard structure with a reeling device according to claim 1, wherein said casing of said reeling cartridge further has thereinside a wire housing for accommodating said reeling mechanism.

16. The keyboard structure with a reeling device according to claim 1, wherein said reeling cartridge is separable from said accommodation slot.
